(19) United States
(12) Patent Application Publication
(10) Pub. No.: US 2013/0277094 A1
(43) Pub. Date: Oct. 24, 2013

(54) TOUCH PANEL AND METHOD FOR MANUFACTURING THE SAME

(71) Applicant: Wan Jae Lee, Gyunggi-do (KR)

(72) Inventor: Wan Jae Lee, Gyunggi-do (KR)

(73) Assignee: SAMSUNG ELECTRO-MECHANICS CO., LTD., Gyunggi-do (KR)

(21) Appl. No.: 13/584,551

(22) Filed: Aug. 13, 2012

(30) Foreign Application Priority Data
Apr. 19, 2012 (KR) 1020120040987

(51) Int. Cl. H05K 3/10; H05K 1/02

(52) U.S. Cl. 174/254; 29/846

(57) ABSTRACT

Disclosed herein are a touch panel and a method for manufacturing the same. The touch panel includes a transparent substrate; electrode patterns formed on the transparent substrate; electrode wirings formed on the transparent substrate and electrically connected with the electrode patterns; a flexible printed circuit board (FPCB) having connection parts electrically connected with the electrode wirings while being connected with a connection region of the transparent substrate on which distal ends of the electrode wirings are disposed; and an adhesive layer formed on the transparent substrate so as to cover the connection parts.

### CROSS REFERENCE TO RELATED APPLICATION

This application claims the benefit of Korean Patent Application No. 10-2012-0040987, filed on Apr. 19, 2012, entitled “Touch Panel And Method For Manufacturing The Same”, which is hereby incorporated by reference in its entirety into this application.

### BACKGROUND OF THE INVENTION

1. Technical Field

The present invention relates to a touch panel and a method for manufacturing the same.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has widened the use of computers more and more, it is difficult to efficiently operate products using only a keyboard and a mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

The touch panel is mounted on display surfaces of a flat panel display device including an electronic organizer, a liquid crystal display (LCD) device, a plasma display panel (PDP), an electroluminescence (El) element, or the like, or an image display device such as a cathode ray tube (CRT) to thereby be used to allow a user to select desired information while viewing the image display device.

The touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

However, a process of manufacturing a touch panel according to the prior art includes connecting a flexible printed circuit board (FPCB) and therefore, needs to perform reprocessing for facilitating the connection of the flexible printed circuit board.

An example of the touch panel according to the prior art that performs the preprocessing may include Korean Patent 10-1064645. The touch panel disclosed in the Patent has a pad part for the flexible printed circuit board for connecting transparent electrodes with the flexible printed circuit board formed on a top substrate. Further, a first optical transparent adhesive layer is subjected to a process of partially cutting the first optical transparent adhesive layer with laser so as to expose the pad part. Further, a second optical transparent adhesive layer and the top substrate are subjected to partially cutting the second optical transparent adhesive layer and the top substrate with laser so as to connect the transparent electrode formed on the bottom substrate with the flexible printed circuit board.

An example of another prior art may include Korean Patent Laid-Open Publication No. 10-2011-0098294. The process of manufacturing a touch panel according to the prior art disclosed in the Publication Patent includes supplying a PET film, supplying a conductive polymer transparent electrode, printing a conductive polymer transparent electrode, printing a conductive pattern, supplying an adhesive, supplying a protective film, and cutting the protective film. In this configuration, the PET film on which the transparent electrode and the conductive pattern are printed is applied with an adhesive by an adhesive supplying unit. In this process, the cutting of partially cutting the adhesive (OCA film) is performed. The process of manufacturing a touch panel includes stacking the OCA film on the PET film and connecting the flexible printed circuit board on the conductive pattern on the PET film. In this case, only when a portion in which the flexible printed circuit board in the conductive pattern portion on the PET film is connected is not covered with the OCA film, the flexible printed circuit board may be connected with the conductive pattern. Therefore, the OCA film region corresponding to the conductive pattern portion is necessarily subjected to the preprocessing of the cutting so as not to cover the conductive pattern portion on the PET film connected with the flexible printed circuit board with the OCA film. The touch panel manufactured by the process has a structure in which the OCA film is stacked on the top and bottom substrates, in a state in which the region corresponding to the conductive pattern portion connected with the flexible printed circuit board is cut.

As such, the process of manufacturing a touch panel according to the prior art includes partially cutting the optical transparent adhesive layer (OCA film) so as to perform the process of connecting the flexible printed circuit board with the touch panel. Further, the process of manufacturing a touch panel according to the prior art needs to perform a precise align process on the OCA film and the PET film so as to match the cut portion of the OCA film with the conductive pattern portion with which the flexible printed circuit board is connected.

The process of manufacturing a touch panel according to the related art includes additional cutting and aligning requiring precision and therefore, has disadvantages such as manufacturing convenience or manufacturing time.

Meanwhile, the configuration of the touch panel such as the PET film and the OCA film may be prepared and supplied in a roll type. Therefore, when the process of manufacturing a touch panel may be generally performed in a roll to roll process, the manufacturing process may be very advantageous in terms of the manufacturing convenience or the manufacturing time.

However, the process of manufacturing a touch panel according to the related art includes cutting the OCA film and precisely aligning and bonding the cut OCA film on the PET film and thus, it is impossible to realize a complete roll to roll process.

In order to minimize the miss align between the PET film and the OCA film, the PET film needs to be previously cut and supplied in a sheet unit. Further, the OCA film is also previously cut in a sheet unit corresponding to the PET film, the cutting for connecting the flexible printed circuit board is performed, and the aligning for the PET film is performed. Since the precise align between the films can be implemented only when the two films are cut and supplied in the sheet unit, the process of manufacturing a touch panel according to the prior art is hard to realize the overall roll to roll process.

### SUMMARY OF THE INVENTION

The present invention has been made in an effort to provide a touch panel and a method for manufacturing the same, in which a cutting process of an OCA film accompanied by a process of manufacturing a touch panel according to the prior art is omitted.

In addition, the present invention has been made in an effort to provide a touch panel and a method for manufacturing the same, in which a precise aligning process between a PET film and an OCA film accompanied by a process of manufacturing a touch panel according to the prior art is not required.

Further, the present invention has been made in an effort to provide a touch panel and a method for manufacturing the same, in which a process for manufacturing a touch panel can generally realize a roll to roll process

According to a first preferred embodiment of the present invention, there is provided a touch panel, including: a transparent substrate; electrode patterns formed on the transparent substrate; electrode wirings formed on the transparent substrate and electrically connected with the electrode patterns; a flexible printed circuit board (FPCB) electrically connected with the electrode wirings while being connected with a connection region of the transparent substrate on which distal ends of the electrode wirings are disposed; and an adhesive layer formed on the transparent substrate so as to the cover connection parts.

The adhesive layer may be formed on the transparent substrate so as to cover the electrode patterns, the electrode wirings, and the connection parts.

The touch panel may further include a window bonded to the adhesive layer.

The adhesive layer may be made of an optical clear adhesive (OCA).

The connection parts may be connected with the connection region while being bonded to each other by an anisotropic conductive film or an anisotropic conductive adhesive.

According to a second preferred embodiment of the present invention, there is provided a method for manufacturing a touch panel, including: (A) forming electrode patterns and electrode wirings electrically connected with the electrode patterns on a transparent substrate; (B) disposing a release film on the transparent substrate so as to cover a connection region on which distal ends of the electrode wirings are disposed; and (C) forming an adhesive layer on the transparent substrate.

The method for manufacturing a touch panel may further include: after (B) the disposing of the release film, separately fixing a portion of the release film that does not face the connection region to the transparent substrate.

The method for manufacturing a touch panel may further include: after (C) the forming of the adhesive layer, (D) spacing the release film facing the connection region and the adhesive layer apart from the connection region and then, connecting connection parts of the flexible printed circuit board with the connection region.

The connection parts may be connected with the connection region while being bonded to each other by an anisotropic conductive film or an anisotropic conductive adhesive.

The method for manufacturing a touch panel may further include: after (D) the connecting of the connection parts of the flexible printed circuit board, (E) removing the release film from the adhesive layer and then, bonding a portion of the adhesive layer from which the release film is removed to the connection parts.

The method for manufacturing a touch panel may further include: after (E) the bonding of the portion of the adhesive layer to the connection parts, (F) bonding a window to the adhesive layer.

The adhesive layer may be made of an optical clear adhesive (OCA).

According to a third preferred embodiment of the present invention, there is provided a method for manufacturing a touch panel including: (a) supplying a transparent film; (b) forming a transparent substrate region including electrode patterns and electrode wirings electrically connected with the electrode patterns on the transparent film; (c) disposing a release film on the transparent film so as to cover a connection region on which distal ends of the electrode wirings are disposed, in the transparent substrate region; and (d) forming an adhesive layer on the transparent film so as to cover the transparent substrate region.

The method for manufacturing a touch panel may further include: after (c) the disposing of the release film, fixing a portion of the release film that does not face the transparent substrate region to the transparent film.

The method for manufacturing a touch panel may further include: after (d) the forming of the adhesive layer, (e) cutting the transparent substrate region in the transparent film.

The method for manufacturing a touch panel may further include: after (e) the cutting of the transparent substrate region, (f) spacing the release film facing the connection region and the adhesive layer apart from the connection region and then, connecting connection parts of the flexible printed circuit board with the connection region.

The connection parts may be connected with the connection region while being bonded to each other by an anisotropic conductive film or an anisotropic conductive adhesive.

The method for manufacturing a touch panel may further include: after (f) the connecting of the connection parts of the flexible printed circuit board, (g) removing the release film from the adhesive layer and then, bonding a portion of the adhesive layer from which the release film is removed to the connection parts

The method for manufacturing a touch panel may further include: after (g) the bonding of the portion of the adhesive layer to the connection parts, (h) bonding a window to the adhesive layer.

The adhesive layer may be made of an optical clear adhesive (OCA).

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a touch panel according to a preferred embodiment of the present invention;

FIG. 2 is a flow chart schematically showing a method for manufacturing a touch panel according to a preferred embodiment of the present invention;

FIG. 3 is a plan view of a transparent subs ate subjected to step (b) shown in FIG. 2;

FIG. 4 is a cross-sectional view of the transparent substrate subjected to step (c) shown in FIG. 2;

FIG. 5 is a cross-sectional view of the transparent substrate subjected to step (d) shown in FIG. 2;

FIG. 6 is a flow chart schematically showing a method for manufacturing a touch panel according to a preferred embodiment of the present invention; and

FIG. 7 is a plan view of a transparent film subjected to steps (a), (b), and (c).

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

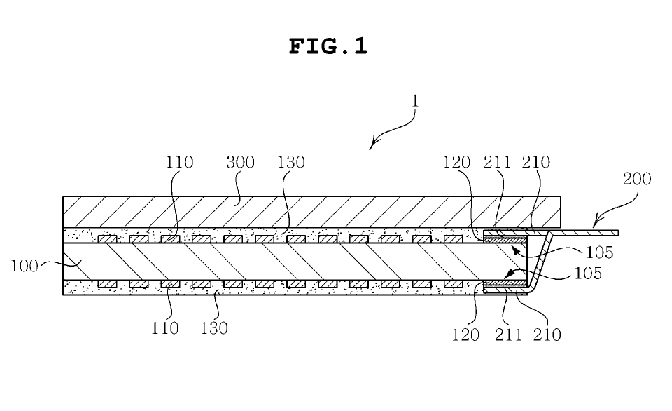

FIG. 1 is a cross-sectional view of a touch panel according to a preferred embodiment of the present invention.

As shown in FIG. 1, a touch panel 1 according to a preferred embodiment of the present invention includes a transparent substrate 100, electrode patterns 110, electrode wirings 120, a flexible printed circuit board (FPCB) 200, and adhesive layers 130.

The transparent substrate 100 provides a region in which the electrode patterns 110 and the electrode wirings 120 to be described below, and the like, are formed. In this configuration, the transparent substrate 100 needs to have a support force supporting the electrode patterns 110, the electrode wirings 120, and the like and transparency enabling a user to recognize images displayed on an image display device. In consideration of the support force and the transparency described above, the transparent substrate 100 may be made of polyethylene terephthalate (PET), polycarbonate (PC), poly methyl methacrylate (PMMA), polyethylene naphthalate (PEN), polyethersulpon (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, or tempered glass, but is not necessarily limited thereto.

Meanwhile, one surface or both surfaces of the transparent substrate 100 are formed with the electrode patterns 110 that can generate signals at the time of touching an input unit (not shown) such as fingers, and the like, to enable an integrated circuit (IC) to recognize touched coordinates.

FIG. 1 shows an example of the touch panel 1 in which the electrode patterns 110 are formed on both surfaces of the transparent substrate 100.

The electrode patterns 110 may be formed as a mesh pattern by using any one of copper (Cu), aluminum (Al), gold (Au), silver (Ag), titanium (Ti), palladium (Pd), and chromium (Cr) or a combination thereof.

When the electrode patterns 110 are made of copper (Cu), a surface of the electrode pattern 110 may be black-oxide treated. In this case, the black-oxide treatment means the case in which Cu2O or CuO is precipitated by oxidizing the surface of the electrode pattern 110 The Cu2O has brown and therefore, is referred to as brown oxide and the CuO has black and therefore, is referred to as black oxide. As such, the surface of the electrode pattern 110 is black-oxide treated to prevent light from being reflected from the electrode pattern 110. Therefore, visibility of the touch panel 1 can be improved.

In addition, in addition to the above-mentioned metals, the electrode pattern 110 may be also made of metal silver formed by exposing/developing a silver salt emulsion layer, indium tin oxide (ITO), PEDOT/PSS, carbon nanotube (CNT), graphene, zinc oxide (ZnO), Al-doped zinc oxide (AZO), and the like.

The electrode wiring(s) 120 is formed on one surface or both surfaces of the transparent substrate 100. In an example of the touch panel 1 shown in FIG. 1, that is, an example of the touch panel 1 in which the electrode patterns 10 are formed on both surfaces of the transparent substrate 100, the electrode wirings 120 may be formed on both surfaces of the transparent substrate 100.

The electrode wirings 120 may be made of any one of copper (Cu), aluminum (Al), gold (Au), silver (Ag), titanium (Ti), palladium (Pd), and chromium (Cr) having excellent electric conductivity or a combination thereof. In addition, the electrode wiring 120 may be also made of metal silver formed by exposing/developing a silver salt emulsion layer, indium tin oxide (ITO), PEDOT/PSS, carbon nanotube (CNT), graphene, zinc oxide (ZnO), Al-doped zinc oxide (AZO), and the like. Further, as needed, the electrode wirings 120 may be integrally with the electrode patterns 110. The electrode wirings 120 are integrally formed with the electrode patterns 110 and thus, bonding defects between the electrode wirings 120 and the electrode patterns 110 can be previously prevented. In addition, the process of manufacturing a touch panel 1 may be more simplified and lead time may be shortened.

The electrode wirings 120 are connected with the electrode patterns 110 to receive electrical signals from the electrode patterns 110. The electrode wirings 120 transfers the received electrical signals to the integrated circuit through the flexible printed circuit board 200.

The flexible printed circuit board 200 is electrically connected with the electrode wirings 120 so as to receive the electrical signals from the electrode wirings 120. In detail, distal ends of the electrode wirings 120 may be disposed at, for example, edges of the transparent substrate 100. The region of the transparent substrate 100 on which the distal ends of the electrode wirings 120 are disposed becomes a connection region 105 in which the flexible printed circuit board 200 is connected with the electrode wirings 120. The flexible printed circuit board 200 is electrically connected with the electrode wirings 120 while connection parts 210 formed at ends thereof is connected with the connection region 105. In this case, the connection parts 210 of the flexible printed circuit board 200 may be connected with the connection region 105 while being bonded to each other by a conductive adhesive material 211, such as an anisotropic conductive film (ACF), anisotropic conductive adhesive (ACA), and the like.

The adhesive layer 130 is a bonding means enabling the window 300, the image display device to be described below, and the like, to the transparent substrate 100. In this case, the adhesive layer 130 may be an optical clear adhesive (OCA), but all types of adhesives known to the art may be used.

The adhesive layer 130 is formed on the transparent substrate so as to cover the connection parts 210 of the flexible printed circuit board 200. In more detail, the adhesive layer 130 is integrally formed to extend to the connection part 210 and may be stacked on the transparent substrate 100 so as to cover the electrode patterns 110, the electrode wirings 120, and the connection parts 210 of the flexible printed circuit board 200 that are described above. The adhesive layer 130 of the touch panel 1 according to the preferred embodiment of the present invention is not subjected to a pre-cutting process for connecting with the flexible printed circuit board 200, unlike the adhesive layer of the touch panel according to the prior art. Therefore, as shown in FIG. 1, the adhesive layer 130 is stacked in a region in which the electrode patterns 110 and the electrode wirings 120 are formed and integrally stacked on the transparent substrate 100 extending to the connection parts 210 of the flexible printed circuit board 200.

The touch panel 1 according to the preferred embodiment of the present invention has many advantages in terms of manufacturing convenience and manufacturing time due to the removal of the cutting of the adhesive layer 130, as compared with the touch panel according to the prior art. In addition, the touch panel according to the prior art is manufactured through the cutting process of the adhesive layer and therefore, needs the additional adhesive layer covering the connection parts 210 of the flexible printed circuit board 200 so as to bond the window 300 or the image display device to the transparent substrate 100. The touch panel 1 according to the preferred embodiment of the present invention does not need to include the process of forming a separate adhesive layer covering the connection parts 210 of the flexible printed circuit board 200 since the adhesive layer 130 is integrally formed on the transparent substrate 100 so as to extend to and cover the connection parts 210 of the flexible printed circuit board 200.

The touch panel 1 according to the preferred embodiment of the present invention may further include the window 300 bonded to the adhesive layer 130.

The window 300 is provided at an outermost side of the touch panel 1 to protect inner components of the touch panel 1, such as the electrode patterns 110, the electrode wirings 120, and the like. Further, the window 300 is a member to which a touch is directly applied by the input unit. Here, a material of the window 300 is not particularly limited. The window 300 may be made of glass, tempered glass, and the like. Further, the window 300 may cover the electrode wirings 120 formed on one surface thereof or a printing unit (not shown) displaying a logo, and the like.

As described above, in the touch panel 1 according to the preferred embodiment of the present invention, since the adhesive layer 130 is extendedly formed to cover the connection parts 210, the window 300 may be bonded to the adhesive layer 130 at a time over the entire area corresponding to the region on the transparent substrate 100 including the connection parts 210 region even though the separate adhesive layer for bonding between the window 300 and the connection parts 210 is not formed.

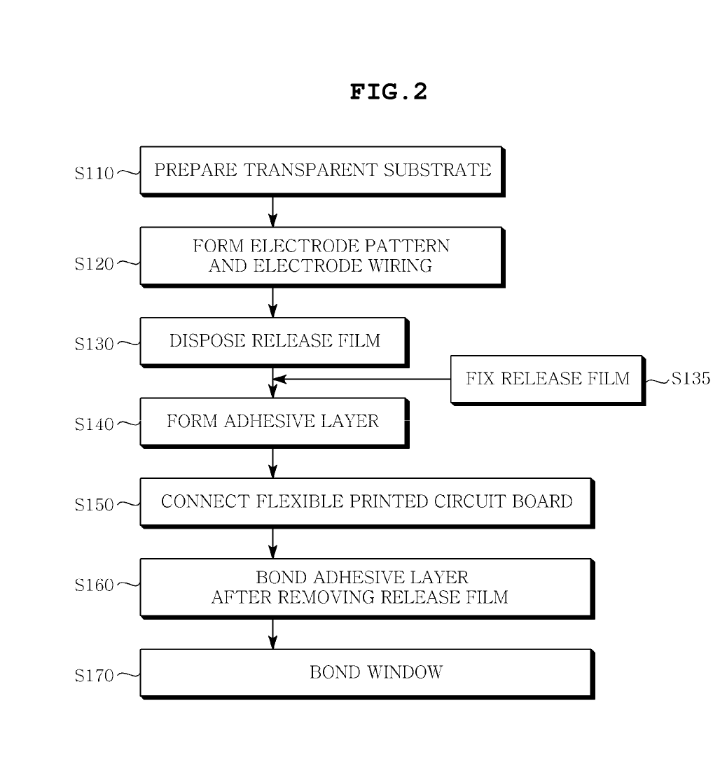

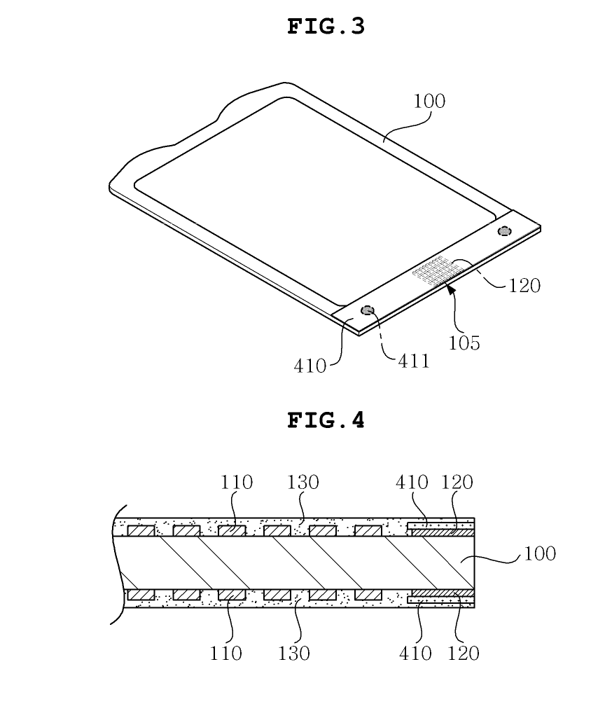

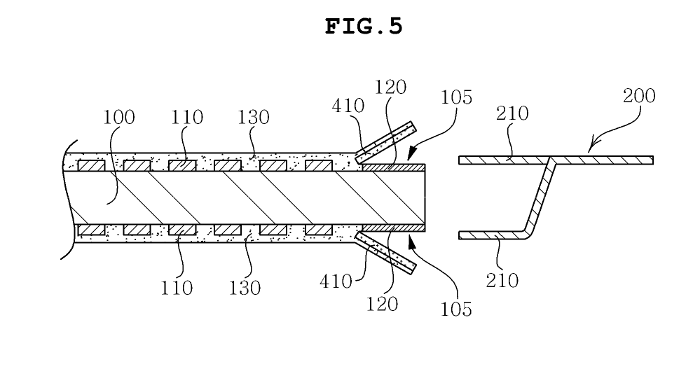

FIG. 2 is a flow chart schematically showing a method for manufacturing a touch panel according to a preferred embodiment of the present invention, FIG. 3 is a plan view of a transparent substrate subjected to step (b) shown in FIG. 2, FIG. 4 is a cross-sectional view of the transparent substrate subjected to step (c) shown in FIG. 2, and FIG. 5 is a cross-sectional view of the transparent substrate subjected to step (d) shown in FIG. 2.

As shown in FIG. 2, a method for manufacturing a touch panel according to the preferred embodiment of the present invention includes: (A) forming the electrode wirings 120 electrically connecting the electrode patterns 110 with the electrode patterns on the transparent substrate 100; (B) disposing a release film 410 on the transparent substrate so as to cover the connection regions 105 on which the distal ends of the electrode wirings are disposed; and (C) forming the adhesive layer 130 on the transparent substrate.

Step (A) is a step of forming the electrode patterns 110 and the electrode wirings 120 on the transparent substrate 100 (S 120), in the state in which the transparent substrate 100 is prepared (S110). Step (A) is performed using the known appropriate processes according to materials of the electrode patterns 110 and the electrode wirings 120. For example, step (A) may be performed using various known processes, such as a plating process, a deposition process using sputter, inkjet printing, and the like, when the electrode patterns 110 and the electrode wirings 120 are made of the above-mentioned metal materials.

Step (B) is a step of disposing release films 410 and 420 on the connection regions 105. The connection regions 105 means a region in which the connection parts 210 of the flexible printed circuit board 200 are connected with the transparent substrate 100 so as to be electrically connected with the electrode wirings 120. As shown in FIG. 3, the connection region 105 is an edge region on the transparent substrate 100 on which the distal ends of the electrode wirings 120 are generally disposed. The release film 410 is disposed on the transparent substrate 100 so as to cover the connection regions 105. The release film 410 covers the region of the transparent substrate 100 including the connection regions 105 without requiring the separate cutting process on the release film 410 but may be formed at a size that is not protruded out of the region of the transparent substrate 100. The release film 410 does not have adhesion and therefore, contacts the connection region 105 in the state in which the release film 410 is disposed in the connection region 105 and is not bonded to the connection region 105.

Meanwhile, the method for manufacturing a touch panel according to the preferred embodiment of the present invention may further include fixing the release films 410 and 420 to the transparent substrate 100 after step (B) (S135). In detail, the present step further includes keeping the release film 410 at the original position without moving on the transparent substrate 100 at the time of performing the forming of the adhesive layer 130 to be described below (S140). In this case, the release film 410 may separately be fixed to the transparent substrate 100 since the release film 410 may be spaced apart from the connection region 105 at the time of performing the connecting of the connection parts 210 to be described below (S150). In more detail, as shown in FIG. 3, the release film 410 may be fixed to the transparent substrate 100 so as to separate from the transparent substrate 100 by various methods such as thermo-compression so that a portion where the connection regions 105 do not face each other is bonded by an adhesive having weak adhesion or temporally bonded, when a predetermined force is applied to the release film 410. As shown in FIG. 3, reference numeral 411 shows a portion of the release film 410 bonded to the transparent substrate 100 by an adhesive or thermally compressed thereto.

As shown in FIG. 4, step (C) is a step of forming the adhesive layer 130 on the transparent substrate 100 in the state in which the release film 410 is disposed on the transparent substrate 100 (S410). Here, as described above, an example of the adhesive layer 130 may include an optical clear adhesive (OCA). In the method for manufacturing a touch panel according to the preferred embodiment of the present invention, the adhesive layer 130 does not directly contact the connection region 105 by interposing the release film 410 covering the connection region 105 between the connection region 105 and the adhesive layer 130 of the transparent substrate 100 according to step C. Therefore, according to the method for manufacturing a touch panel according to the preferred embodiment of the present invention, the cutting of the predetermined portion of the adhesive layer 130 corresponding to the connection region 105 is not required.

The method for manufacturing a touch panel according to the preferred embodiment of the present invention may further include (D) connecting the connection parts 210 of the flexible printed circuit board 200 with the connection region 105 (S150). The present step is performed after the above-mentioned step (C). Since the release film 410 is disposed by contacting the connection region 105 and is not bonded to the connection region 105, the release film 410 may be spaced apart from the connection region 105. Even though the fixing (S135) of the above-mentioned release film 410 is further performed, the portion where the connection regions 105 do not face each other is separately fixed to the transparent substrate 100 and thus, the release film 410 may be easily spaced apart from the connection region 105 when the release film 400 is lifted by applying the predetermined force. When the release film 410 facing the connection region 105 and the portion of the adhesive layer 130 formed on the release film 410 are spaced apart from the connection region 105, as shown in FIG. 5, the connection region 105 is exposed to the outside. The connection parts 210 of the flexible printed circuit board 200 may be easily connected with the exposed connection region 105. In this case, the connection parts 210 may be connected with the connection region 105 while being bonded with the connection region 105 by the conductive adhesive material 211 (see FIG. 1) such as the anisotropic conductive film, the anisotropic conductive adhesive, and the like, so as to maintain the state in which the connection parts 210 are connected to the connection region 105. The connection parts 210 are electrically connected with the connection region 105 and thus, the flexible printed circuit board 105 is electrically connected with the electrode wirings 120.

The method for manufacturing a touch panel according to the preferred embodiment of the present invention may further include (E) bonding the portion of the adhesive layer 130 to the connection parts 210 after the above-mentioned step (D). The release film 410 may be easily separated from the portion of the adhesive layer 130 formed on the release film 410. When the release film 410 is removed by separating from the adhesive layer 130, the portion of the adhesive layer 130 facing the connection part 210 is exposed and the portion of the exposed adhesive layer 130 may be bonded to the connection part 210. The adhesive layer 130 is bonded to the connection part 210 and thus, as shown in FIG. 1, the adhesive layer 130 is formed on the transparent substrate 100 so as to cover the region on the transparent substrate 100 including the electrode patterns 110 and the electrode wirings 120 and the region extending to the connection part 210.

The method for manufacturing a touch panel according to the preferred embodiment of the present invention may further include (F) bonding the window 300 (see FIG. 1) to the adhesive layer 130 (S170) after step (E). According to the method for manufacturing a touch panel according to the preferred embodiment of the present invention, since the adhesive layer 130 is integrally formed on the transparent substrate 100 so as to extend to the connection part 210, even though the separate adhesive layer 130 for bonding between the window 300 and the connection part 210 is not formed, the window 300 may be bonded to the adhesive layer 130 at a time over the area of the window 300 corresponding to the region on the transparent substrate 100 including the connection part 210 region.

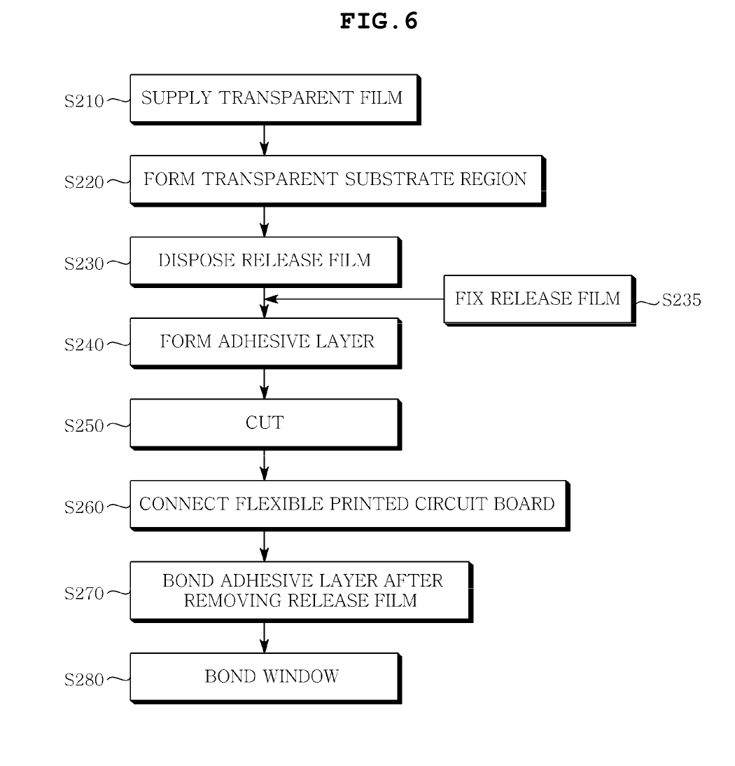

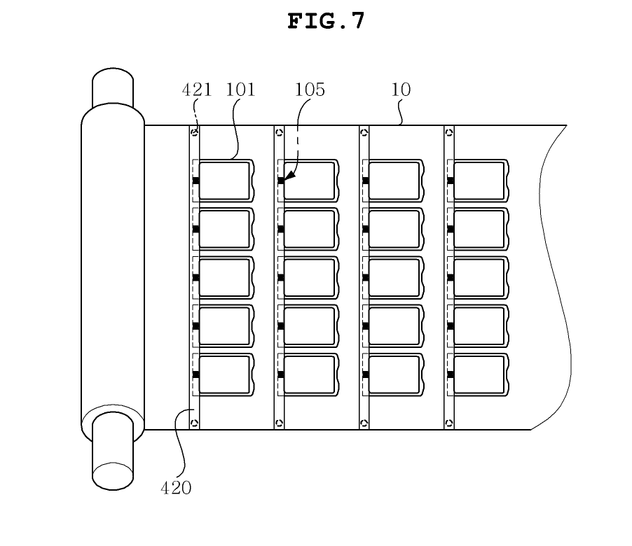

FIG. 6 is a flow chart schematically showing a method for manufacturing a touch panel according to a preferred embodiment of the present invention and FIG. 7 is a plan view of a transparent film subjected to steps (a), (b), and (c) shown in FIG. 6.

A method for manufacturing a touch panel according to the preferred embodiment of the present invention includes: (a) supplying the transparent film 10; (b) forming a transparent substrate region 101 including the electrode pattern 110 and the electrode wirings 120 electrically connected to the electrode patterns on the transparent film 10; (c) disposing the release film 420 on the transparent film 10 so as to cover the connection region 105 on which the distal ends of the electrode wirings 120 are disposed in the transparent substrate region 101; and (d) forming the adhesive layer 130 on the transparent film 10 so as to cover the transparent substrate region 101.

(a) As shown in FIG. 7, the supplying of the transparent film 10 (S210) may include supplying a roll type of the transparent film 10. The transparent film 10 may be made of the same materials as those of the above-mentioned transparent substrate 100 and thus, may be prepared and supplied in the roll type when it is made of materials having flexibility.

Step (b) is a step of forming the transparent substrate region 101 including the electrode patterns 110 and the electrode wirings 120 on the transparent film 10 (S220). The electrode patterns 110 and the electrode wirings 120 are formed by a variety of known patterning processes, and the like, during the supplying of the transparent film 10. In addition, the predetermined region of the transparent film 10 including the electrode patterns 110 and the electrode wirings 120 is a single touch panel cell forming the transparent substrate 100 described in the one preferred embodiment of the present invention by performing the cutting process on the subsequent transparent film 10. The transparent substrate region 101 means the touch panel cell region. The region on which the distal ends of the electrode wirings 120 are disposed in the transparent substrate region 101 becomes the above-mentioned connection region 105. At least one transparent substrate region 101 may be formed on the transparent film 10.

Step (c) is a step (S230) of disposing the release film 420. The release film 420 is disposed on the transparent film 10 so as to cover the connection regions 105. As shown in FIG. 7, the plurality of transparent substrate regions 101 are formed on the transparent film 10 and when the plurality of transparent substrate regions 101 are spaced apart from each other at equidistance while forming a plurality of matrices, the connection region 105 is also positioned so as to be spaced apart from each other on the transparent film 10 Therefore, the release film 420 may be formed in a long strip shape so as to cover the plurality of connection regions 105 at a time. Further, the release film 420 may be disposed on the transparent film 10 while traversing the transparent film 10.

The method for manufacturing a touch panel according to the preferred embodiment of the present invention may further include fixing the release film 420 to the transparent film 10 after step (c). In detail, in the release film 420, the portion which does not face the transparent substrate regions 101 is fixed to the transparent film 10. In this case, as the above-mentioned one preferred embodiment of the present invention, the release film 420 in the present step may be separately fixed to the transparent film 10 but may be fixed on the transparent film 10 so as not to be separated When the cutting of the transparent substrate region to be described below (S250) is performed, the portion of the release film 420 that does not face the transparent substrate region 101 is separated from the release film 420 disposed on the transparent substrate region 101. In this case, the release film 420 disposed on the transparent substrate region 101 keeps an original position by the adhesive layer 130 formed by performing the forming of the adhesive layer (S240) to be described below and may be easily spaced apart from the connection region 105. Therefore, the release film 420 disposed on the transparent film 10 may be fixed to the transparent film 10 so that the portion that does not face the transparent substrate region 101 is not separated from the transparent film 10. FIG. 7 shows an example in which a predetermined portion 421 of both ends of the release film 420 facing the transparent film 10 region other than the transparent substrate region 101 is fixed to the transparent film 10 by an adhesive or various methods such as thermo compression, and the like.

The method for manufacturing a touch panel according to the preferred embodiment of the present invention includes (d) forming the adhesive layer 130 on the transparent film 10 (S240), after the above-mentioned step (c) is performed or after step (c) is performed and then, the fixing of the above-mentioned release film 420 is continuously performed (S235). An example of the adhesive layer 130 may include an optical clear adhesive (OCA). In this case, as the adhesive layer 130, ones formed in the film type may be used. In this case, the adhesive layer 130 may be formed on the transparent film 10 while being prepared and supplied in the roll type. During this process, the method for manufacturing a touch panel according to the preferred embodiment of the present invention do not have to perform the cutting of the adhesive layer 130 region corresponding to the connection region 105 by including the disposing of the above-mentioned release film 420 (S230). In addition, the method for manufacturing a touch panel according to the preferred embodiment of the present invention does not have to perform the precise align process between the adhesive layer and the transparent film that matches the cut portion of the adhesive layer and the connection region, which is performed during the process of manufacturing a touch panel according to the related art including the cutting of the adhesive layer 130. In the method for manufacturing a touch panel according to the preferred embodiment of the present invention, the forming of the adhesive layer 130 on the transparent film 10 (S240) may be completed by performing a process of supplying the adhesive layer 130 to the transparent film 10 in a roll type only once without performing the above-mentioned cutting or align process. Therefore, according to the method for manufacturing a touch panel according to the preferred embodiment of the present invention, the number of processes can be reduced, the manufacturing costs can be reduced, the manufacturing time can be greatly shortened, and the manufacturing convenience can be greatly improved.

The method for manufacturing a touch panel according to the preferred embodiment of the present invention may further include (e) cutting the transparent substrate region 101 in the transparent film 10 (S250) after step (d). The transparent substrate region 101 cut in the transparent film 10 becomes the transparent substrate 100 configuring the single touch panel.

The method for manufacturing a touch panel according to the preferred embodiment of the present invention may include after step (e), (f) spacing the release film 420 facing the connection region 105 and the adhesive layer 130 apart from the connection region 105 and then connecting the connection part 210 of the flexible printed circuit board 210 with the connection region 105. In this case, the connection part 210 may be connected with the connection region 105 while being bonded to each other by the conductive adhesive materials 211 such as the anisotropic conductive film, the to anisotropic conductive adhesive, and the like.

In addition, after step (f), the method for manufacturing a touch panel according to the preferred embodiment of the present invention may further include (g) removing the release films 410 and 420 from the adhesive layer 130 and then, bonding the portion of the adhesive layer 130 from which the release film 420 is removed to the connection part 210 (S270).

In addition, after step (g), the method for manufacturing a touch panel according to the preferred embodiment of the present invention may include (h) bonding the window 300 to the adhesive layer 130 (S280).

In this case, step (f), step (g), and step (h) are the same as step (D), step (E), and step (F), respectively in the method for manufacturing a touch panel according to the preferred embodiment of the present invention and therefore, may be replaced by the description of the preferred embodiment of the present invention. Herein, the detailed description thereof will be omitted.

The touch panel according to the preferred embodiments of the present invention has an advantage in that the adhesive layer formed on the transparent substrate is formed to cover the connection parts of the flexible printed circuit board connected with the transparent substrate, thereby omitting the cutting process of the adhesive layer corresponding to the connection region.

Further, the adhesive layer is integrally formed by extending to the connection parts on the transparent substrate and therefore, the window can be bonded to the adhesive layer at a time even though a separate adhesive layer is not further formed on the connection parts.

The method for manufacturing a touch panel according to the preferred embodiments of the present invention can easily connect the connection part of the flexible printed circuit board even though the adhesive layer is integrally formed to extend to the connection region by interposing the release film between the connection region and the adhesive layer when the adhesive layer is formed on the transparent substrate or the transparent film. According to the preferred embodiment of the present invention, the cutting of the adhesive layer region corresponding to the connection region can be omitted. Therefore, the precise align process between the transparent substrate or the transparent film and the adhesive layer is not required. Therefore, the method for manufacturing a touch panel according to the preferred embodiment of the present invention can reduce the number of manufacturing processes and the manufacturing time, and greatly improve the manufacturing convenience.

Meanwhile, both of the transparent film and the adhesive layer are formed in the film type and thus, can be prepared and supplied in the roll type. In this case, according to the method for manufacturing a touch panel according to the preferred embodiment of the present invention, the process of manufacturing a touch panel can be realized by the complete roll to roll process before the cutting of the transparent substrate region since the cutting of the adhesive layer is omitted and the precise align process between the transparent film and the adhesive layer is not required.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
a transparent substrate;
electrode patterns formed on the transparent substrate;
electrode wirings formed on the transparent substrate and electrically connected with the electrode patterns;
a flexible printed circuit board (FPCB) having connection parts electrically connected with the electrode wirings while being connected with a connection region of the transparent substrate on which distal ends of the electrode wirings are disposed; and
an adhesive layer formed on the transparent substrate so as to cover the connection parts.

2. The touch panel as set forth in claim 1, wherein the adhesive layer is formed on the transparent substrate so as to cover the electrode patterns, the electrode wirings, and the connection parts.

3. The touch panel as set forth in claim 1, further comprising: a window bonded to the adhesive layer.

4. The touch panel as set forth in claim 1, wherein the adhesive layer is made of an optical clear adhesive (OCA).

5. The touch panel as set forth in claim 1, wherein the connection parts are connected with the connection region while being bonded to each other by an anisotropic conductive film or an anisotropic conductive adhesive.

6. A method for manufacturing a touch panel, comprising:
(A) forming electrode patterns and electrode wirings electrically connected with the electrode patterns on a transparent substrate;
(B) disposing a release film on the transparent substrate so as to cover a connection region on which distal ends of the electrode wirings are disposed; and
(C) forming an adhesive layer on the transparent substrate.

7. The method as set forth in claim 6, further comprising: after (B) the disposing of the release film, separately fixing a portion of the release film that does not face the connection region to the transparent substrate.

8. The method as set forth in claim 6, further comprising: after (C) the forming of the adhesive layer, (D) spacing the release film facing the connection region and the adhesive layer apart from the connection region and then, connecting connection parts of the flexible printed circuit board with the connection region.

9. The method as set forth in claim 8, wherein the connection parts are connected with the connection region while being bonded to each other by an anisotropic conductive film or an anisotropic conductive adhesive.

10. The method as set forth in claim 8, further comprising: after (D) the connecting of the connection parts of the flexible printed circuit board, (E) removing the release film from the adhesive layer and then, bonding a portion of the adhesive layer from which the release film is removed to the connection parts.

11. The method as set forth in claim 10, further comprising: after (E) the bonding of the portion of the adhesive layer to the connection parts, (F) bonding a window to the adhesive layer.

12. The method as set forth in claim 6, wherein the adhesive layer is made of an optical clear adhesive (OCA).

13. A method for manufacturing a touch panel, comprising:
(a) supplying a transparent film;
(b) forming a transparent substrate region including electrode patterns and electrode wirings electrically connected with the electrode patterns on the transparent film;
(c) disposing a release film on the transparent film so as to cover a connection region on which distal ends of the electrode wirings are disposed, in the transparent substrate region; and
(d) forming an adhesive layer on the transparent film so as to cover the transparent substrate region.

14. The method as set forth in claim 13, further comprising: after (c) the disposing of the release film, fixing a portion of the release film that does not face the transparent substrate region to the transparent film.

15. The method as set forth in claim 13, further comprising: after (d) the forming of the adhesive layer, (e) cutting the transparent substrate region in the transparent film.

16. The method as set forth in claim 15, further comprising: after (e) the cutting of the transparent substrate region, (f) spacing the release film facing the connection region and the adhesive layer apart from the connection region and then, connecting connection parts of the flexible printed circuit board with the connection region.

17. The method as set forth in claim 16, wherein the connection parts are connected with the connection region while being bonded to each other by an anisotropic conductive film or an anisotropic conductive adhesive.

18. The method as set forth in claim 16, further comprising: after (f) the connecting of the connection parts of the flexible printed circuit board, (g) removing the release film from the adhesive layer and then, bonding a portion of the adhesive layer from which the release film is removed to the connection parts.

19. The method as set forth in claim 18, further comprising: after (g) the bonding of the portion of the adhesive layer to the connection parts, (h) bonding a window to the adhesive layer.

20. The method as set forth in claim 13, wherein the adhesive layer is made of an optical clear adhesive (OCA).
